(19) United States
(12) Patent Application Publication
(10) Pub. No.: US 2008/0080232 A1
(43) Pub. Date: Apr. 3, 2008

(54) Active write current adjustment for magneto-resistive random access memory

(76) Inventors: Andre Sturm, Essex Junction, VT (US); Hans-Heinrich Viehmann, Munich (DE); Dietmar Gogl, Essex Junction, VT (US)

Correspondence Address: SLATER & MATSIL LLP, 17950 PRESTON ROAD, SUITE 1000, DALLAS, TX, 75252, US

(21) Appl. No.: 11/529,569

(22) Filed: Sep. 28, 2006

(51) Int. Cl. G11C 11/00; G11C 11/14; G11C 11/15

(52) U.S. Cl. 365/158; 365/171; 365/173

(57) ABSTRACT

In a method of programming a magneto resistive memory cell, a first magnetic field is applied to the magneto resistive memory cell. It is determined whether the magneto resistive memory cell meets a programming criterion. In case that the magneto resistive memory cell does not meet the programming criterion, a second magnetic field, which is higher or lower than the first magnetic field, is applied to the magneto resistive memory cell. It is then determined whether the magneto resistive memory cell meets a programming criterion. The magnetic field is increased or decreased in case that the magneto resistive memory cell does not meet the programming criterion until the magneto resistive memory cell meets the programming criterion.

### TECHNICAL FIELD

The present invention relates generally to MRAM (Magneto-resistive Random Access Memory) devices, and more particularly to a method for adjusting the write current for MRAM devices.

### BACKGROUND

One emerging technology for non-volatile memory is magneto-resistive random access memory (MRAM). At present, the most common form of MRAM is based on the tunnelling magneto-resistance (TMR) effect, in which each memory cell comprises a magnetic tunnel junction (MTJ). Such an MTJ may be formed from two ferromagnetic metal layers, with an insulating layer placed between the metal layers. When a voltage is applied between the metal layers, a tunnel current flows. The tunnel resistance varies based on the relative directions of magnetization of the metal layers. The tunnel resistance is small when the directions of magnetization are parallel (typically representing a “0”), and large (approximately 10%-20% higher, at room temperature) when the directions of magnetization are anti-parallel (typically representing a “1”).

The metal layers in a typical MRAM MTJ include a “fixed” layer, in which the direction of the magnetization is fixed, and a “free” layer, in which the direction of the magnetization can be switched by application of currents. These currents are applied through conductive write lines referred to as bit lines and word lines, which are disposed so that the bit lines are orthogonal to the word lines. In an MRAM array, an MTJ memory cell is located at each intersection of a bit line with a word line.

To switch the direction of magnetization of the free layer of a particular cell, currents are applied through the bit line and the word line that intersect at that cell. The direction of these currents determines the direction in which the magnetization of the free layer will be set. The combined magnitude of the currents through the word and bit lines must be sufficient to generate a magnetic field at their intersection that is strong enough to switch the direction of magnetization of the free layer.

For a type of switching known as Stoner-Wohlfahrt switching, the magnetic orientation of the free and fixed layers are in the same direction (parallel or anti-parallel) as the direction of the bit line field. Thus, the direction of the current through the bit line determines whether a logical “0” or “1” is written to the cell, while the direction of the current through the word line need not vary.

For a type of switching known as rotational switching (also referred to as toggle switching), the magnetic orientation of the free and fixed layer are rotated at a forty-five degree angle with respect to the directions of the bit line and word line. To write a logical “0” or “1,” the cell is first read. Currents are only applied through the bit line and word line if the cell is not already in the desired state. The directions of the current through the bit line and word line always remain the same, and cause the logical value written to the cell to be toggled. Thus, if the cell contained a “0,” then application of current on the bit line and word line will cause it to switch to a “1,” and if the cell contained a “1,” then application of current will cause it to switch to a “0.”

One difficulty with current MRAM devices relates to the current that is used to write to the memory cells. Because the MTJs in an MRAM memory array are programmed using the magnetic fields of the word lines and bit lines, the presence of stray or external fields during the write operation can cause the wrong information to be written to memory cells. If the write current in the bit lines and/or word lines is too low, such external magnetic fields may disturb the writing of a value to a cell, or cause the wrong value to be written.

Additionally, due to manufacturing conditions, the write current required to write data to cells in an MRAM array may vary. For example, even a relatively slight offset shift during fabrication can cause the cells to require a greater write current, since they will not be properly aligned between the bit lines and word lines. This can, of course, be solved by discarding those devices that exhibit this manufacturing flaw, but this would reduce the yield, increasing the average cost of MRAM devices. Other effects, such as electrical and magnetic effects within the chip, can also lead to some cells in the array requiring a greater write current than others.

One solution might be to use a relatively high write current, sufficient to write to any of the memory cells, despite external fields, manufacturing problems, etc. Unfortunately, this solution fails, because there are a variety of difficulties that can occur when too much write current is applied to either the bit line or the word line. First, if too much current is applied, the field will be too great, and the cell may not switch reliably. Even when the write current is low enough to reliably switch a cell, the field generated may be sufficient to inadvertently switch memory cells adjacent to the cell that is intended to be switched. Additionally, if the current on either the bit line or the word line is high enough, the magnetic field of the bit line and/or word line may be sufficient to switch some of the cells along that line, even in the absence of a field from an intersecting line.

What is needed in the art is a way to apply a write current to each cell in an MRAM array that is sufficient to write a value to the cell, while compensating for the presence of any external field, and taking into account the type of switching that is used by the MRAM array.

### SUMMARY OF THE INVENTION

One embodiment of the invention provides a method of programming a magneto resistive memory cell. A first magnetic field is applied to the magneto resistive memory cell. It is determined whether the magneto resistive memory cell meets a programming criterion. In case that the magneto resistive memory cell does not meet the programming criterion, a second magnetic field, which is higher or lower than the first magnetic field, is applied to the magneto resistive memory cell. It is then determined whether the magneto resistive memory cell meets a programming criterion. The magnetic field is increased or decreased in case that the magneto resistive memory cell does not meet the programming criterion until the magneto resistive memory cell meets the programming criterion.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a perspective view of an MRAM array in accordance with an exemplary embodiment of the invention;

FIG. 2 shows a perspective view of an MRAM array arrangement in accordance with an exemplary embodiment of the invention;

FIGS. 3A to 3C show a flow diagram illustrating a method of programming a magneto resistive memory cell in accordance with an exemplary embodiment of the invention using Stoner-Wohlfarth type switching; and

FIG. 4 shows a flow diagram illustrating a method of programming a magneto resistive memory cell in accordance with an exemplary embodiment of the invention using rotational type switching.

### DETAILED DESCRIPTION OF ILLUSTRATIVE EMBODIMENTS

In one embodiment of the invention, a method of programming a magneto resistive memory cell is provided, comprising applying a first write current to the magneto resistive memory cell and determining whether the magneto resistive memory cell meets a programming criterion. In case that the magneto resistive memory cell does not meet the programming criterion, applying a second write current to the magneto resistive memory cell that is higher or lower than the first write current. Determining whether the magneto resistive memory cell meets a programming criterion and the increase or decrease of the write current in case that the magneto resistive memory cell does not meet the programming criterion is repeated until the magneto resistive memory cell meets the programming criterion.

The programming may be performed using a Stoner Wohlfarth switching mechanism.

In another embodiment of the invention, the programming may be performed using rotational type switching mechanism.

In another embodiment of the invention, a method of programming magneto resistive memory cells is provided, comprising applying a first write current to a first magneto resistive memory cell to write a first programming value into the first magneto resistive memory cell, applying a second write current to a second magneto resistive memory cell to write a second programming value into the second magneto resistive memory cell, the second programming value being different from the first programming value, and determining whether the magneto resistive memory cells meet a programming criterion. In case that the first magneto resistive memory cell or the second magneto resistive memory cell does not meet the programming criterion, applying a third write current to the respective magneto resistive memory cell that is higher or lower than the first magnetic field or the second magnetic field, respectively, the third write current being applied via a first cell control line corresponding to the write direction of the failing magneto resistive memory cell. In case that the first magneto resistive memory cell and the second magneto resistive memory cell do not meet the programming criterion, applying a fourth write current to the respective magneto resistive memory cell that is higher or lower than the first magnetic field or the second magnetic field, respectively, the fourth write current being applied via a second cell control line.

The first cell control line may be the bit line of the respective magneto resistive memory cell. The second cell control line may be the word line of the respective magneto resistive memory cell.

In one embodiment of this aspect of the invention, the programming is performed using Stoner Wohlfarth switching mechanism.

In accordance with yet another embodiment of the invention, a method of programming magneto resistive memory cells is provided, comprising applying a first write current to a first magneto resistive memory cell to write a first programming value into the first magneto resistive memory cell, applying a second write current to a second magneto resistive memory cell to write a second programming value into the second magneto resistive memory cell, the second programming value being different from the first programming value, and determining whether the magneto resistive memory cells meet a programming criterion. In case that the first magneto resistive memory cell or the second magneto resistive memory cell or both magneto resistive memory cells do not meet the programming criterion, applying a third write current to the respective magneto resistive memory cell that is higher or lower than the first magnetic field or the second magnetic field, respectively, the third write current being applied via a first cell control line, and applying a fourth write current to the respective magneto resistive memory cell that is higher or lower than the first magnetic field or the second magnetic field, respectively, the fourth write current being applied via a second cell control line.

The first cell control line may be the bit line of the respective magneto resistive memory cell. The second cell control line may be the word line of the respective magneto resistive memory cell.

In one embodiment of this aspect of the invention, the programming may be performed using rotational type switching mechanism.

In accordance with still another embodiment of the invention, a magneto resistive memory cell arrangement is provided, comprising at least one magneto resistive memory cell, a programming control unit, and a first magnetic field applied to the magneto resistive memory cell. It is determined whether the magneto resistive memory cell meets a programming criterion. In case that the magneto resistive memory cell does not meet the programming criterion, a second magnetic field is applied to the magneto resistive memory cell that is higher or lower than the first magnetic field. Determining whether the magneto resistive memory cell meets a programming criterion and the increase or decrease of the magnetic field in case that the magneto resistive memory cell does not meet the programming criterion is repeated until the magneto resistive memory cell meets the programming criterion.

In accordance with an embodiment of the invention, a magneto resistive memory cell arrangement is provided, comprising an array of a plurality of magneto resistive memory cells, each magneto resistive memory cell being connected to a respective first cell control line and a respective second control line. A programming control unit is connected to the first cell control lines and the second control lines. A first write current is applied to a first magneto resistive memory cell to write a first programming value into the first magneto resistive memory cell. A second write current is applied to a second magneto resistive memory cell to write a second programming value into the second magneto resistive memory cell, the second programming value being different from the first programming value. It is determined whether the magneto resistive memory cells meet a programming criterion. In case that the first magneto resistive memory cell or the second magneto resistive memory cell does not meet the programming criterion, applying a third write current to the respective magneto resistive memory cell that is higher or lower than the first magnetic field or the second magnetic field, respectively, the third write current is applied via a first cell control line corresponding to the write direction of the failing magneto resistive memory cell. In case that the first magneto resistive memory cell and the second magneto resistive memory cell do not meet the programming criterion, applying a fourth write current to the respective magneto resistive memory cell that is higher or lower than the first magnetic field or the second magnetic field, respectively, the fourth write current is applied via a second cell control line.

The first cell control line may be the bit line of the respective magneto resistive memory cell and the second cell control line may be the word line of the respective magneto resistive memory cell.

Furthermore, computer program products of programming a magneto resistive memory cell or of programming magneto resistive memory cells are provided, which, when being executed by a computer, comprise the respective features of the methods as described above and as will described in more detail below.

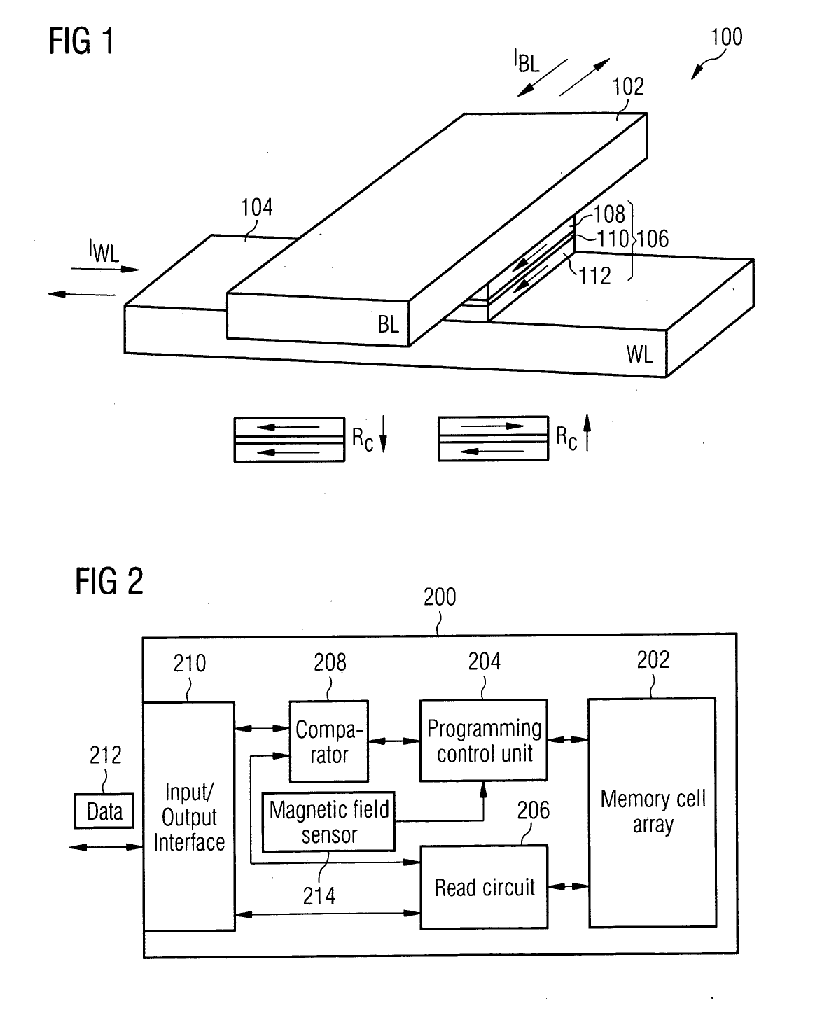

FIG. 1 shows a perspective view of an MRAM cell 100 having a bit line 102 disposed in an orthogonal direction to a word line 104 in adjacent metalization layers. A magnetic memory stack 106 is positioned between the bit line 102 and word line 104 (collectively, write line) at locations where a bit line 102 crosses a word line 104, and, in some embodiments, are electrically coupled to the bit line 102 and word line 104. The magnetic memory stack 106 is, for example, a magnetic tunnel junction (MTJ), comprising multiple layers, including a free layer 108, a tunnel layer 110, and a fixed layer 112. The free layer 108 and fixed layer 112, e.g., comprise a plurality of magnetic metal layers (not shown). These magnetic metal layers may, for example, comprise eight to twelve layers of materials such as PtMn, CoFe, Ru, and NiFe. The tunnel layer 110 comprises a dielectric, such as Al₂O₃.

The fixed layer 112 is e.g. magnetized in a fixed direction, while the direction of magnetization of the free layer 108 may be switched, changing the resistance of the magnetic memory stack 106. One bit of digital information may be stored in a magnetic memory stack 106 by running a current through the bit line 102 and the word line 104 that intersect at the magnetic memory stack 106, creating a sufficient magnetic field to set the direction of magnetization of the free layer 108. Information may be read from a magnetic memory stack 106 by applying a voltage across the magnetic memory stack, and measuring the resistance. If the direction of magnetization of the free layer 108 is parallel to the direction of magnetization of the fixed layer 112, then the measured resistance will be low, representing a value of “0” for the bit. If the direction of magnetization of the free layer 108 is anti-parallel to the direction of magnetization of the fixed layer 112, then the resistance will be high, representing a value of “1.”

Depending on the type of switching that is being used, the method used for writing may be varied. If Stoner-Wohlfahrt switching is being used, then the direction of the current on the bit line 102 will determine the value that is written. If rotational mode switching (also referred to as toggle mode switching) is being used, then the value already stored in a magnetic memory stack 106 needs first to be read. If the value is already the same as the value to be written, then no action is taken. Otherwise, if the value needs to be changed, then current is applied, in a fixed direction, on the word line 104 and bit line 102 to toggle the value stored in the magnetic memory stack 106.

It will be understood that the view shown in FIG. 1 is simplified, and that actual MRAM devices may include additional components. For example, in some MRAM designs, instead of being coupled to both the bit line 102 and word line 104, the magnetic memory stack 106 is coupled to the bit line 102, and to a transistor (not shown), for isolation. It will further be recognized that the view shown in FIG. 1 represents only a small portion of an actual MRAM device. Depending on the organization and memory capacity of the device, there may be hundreds or thousands of bit lines and word lines in a memory array. For example, a 1 Mb MRAM device (i.e., an MRAM device storing approximately one million bits of data) may include two arrays, each of which has 1024 word lines and 512 bit lines. Additionally, in some MRAM devices, there may be multiple layers of magnetic memory stacks, in which layers may share bit lines or word lines.

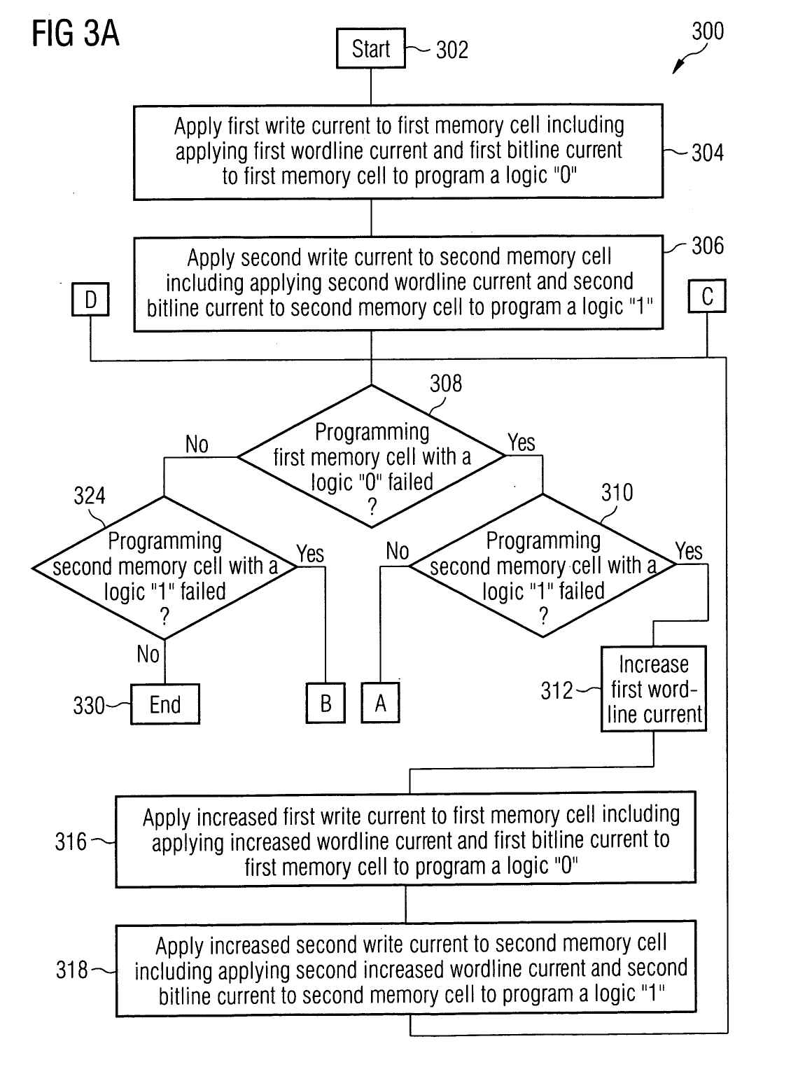

FIG. 2 shows an MRAM device 200 in accordance with an exemplary embodiment of the invention. The MRAM device 200 comprises an MRAM cell array 202 including a plurality of MRAM cells 100 as shown in FIG. 1, which are connected with each other via bit lines 102 and word lines 104, as described above. The bit lines 102 and word lines 104 are connected to a write circuit, also referred to as a programming control unit 204, which performs the necessary steps for writing data into the MRAM cells 100 of the MRAM cell array 202. In other words, the programming control unit 204 performs the steps for programming the MRAM cells 100 of the MRAM cell array 202. Furthermore, the MRAM device 200 comprises a read circuit 206 for reading data that is stored in an MRAM cell 100 of the MRAM cell array 202 from the respective MRAM cell 100. The read circuit 206 is configured in a common way and will therefore not be described in more detail. Moreover, a comparator 208 is provided for comparing the data item that is stored in a respective MRAM cell 100 with the data item that should currently be stored in the MRAM cell 100 during the write operation. The comparator 208 and the read circuit 206 are connected to an input/output interface 210, via which data 212 can be input into the MRAM device 200 or output from the MRAM device 200. Furthermore, at least one input of the comparator 208 is connected to at least one output of the read circuit 206, so that an actual measured value of a respectively addressed MRAM cell can be compared with the desired value the MRAM cell should be programmed with, by means of the comparator 208.

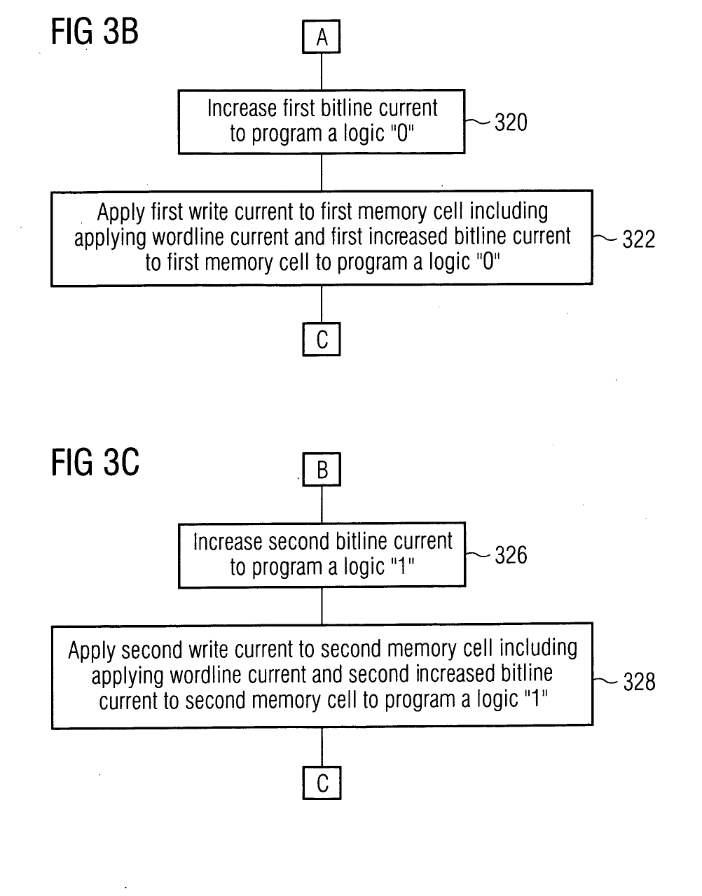

FIGS. 3A and 3B show a flow diagram 300 illustrating a method of programming a magneto resistive memory cell in accordance with an exemplary embodiment of the invention using Stoner-Wohlfarth type switching. The method is implemented using the programming control unit 204, the read circuit 206 and the comparator 208.

As shown in FIG. 3A, when a first data item (a logic “0”) should be written to a specified first MRAM cell of the MRAM cell array 202 and a second data item (a logic “1”) should be written to a specified second MRAM cell of the MRAM cell array 202, the method is started in 302.

Then, a first write current that is normally provided for writing a logic “0” into the first MRAM cell is applied to the first MRAM cell in 304. The application of the first write current includes the application of a word line current and a first bit line current to the first MRAM cell, in other words, to the first word line and the first bit line, which are connected to the first MRAM cell.

Then, a second write current that is normally provided for writing a logic “1” into the second MRAM cell is applied to the second MRAM cell in 306. The application of the second write current includes the application of the word line current and a second bit line current to the second MRAM cell, in other words, to the second word line and the second bit line, which are connected to the second MRAM cell.

In an alternative embodiment of the invention, 304 and 306 are executed simultaneously. In other words, a plurality of bit lines are activated simultaneously. In this way, a plurality of memory cells may be programmed at the same time. In one embodiment of the invention, the first bit line current is used to program a logic “0” (the first bit line runs in a first direction) into a first memory cell and the second bit line current is used to program a logic “1” (the second bit line runs in a second direction, wherein the second direction is opposite to the first direction) into a second memory cell. In other words, in one embodiment of the invention, 304 and 306 are performed simultaneously using the same word line current.

Next, according to this embodiment of the invention, it is determined, using the read circuit 206 and the comparator 208, whether the programming (i.e., the write operation) of a logic “0” of the first MRAM cell has failed or has been successful (operation 308). This operation is carried out in that the actual resistance value of the first MRAM cell representing the logic value being stored in the first MRAM cell is compared with the resistance value that would represent the logic value that should be stored in the first MRAM cell during the write operation.

In case the programming of the logic “0” of the first MRAM cell has failed (“Yes” in 308), it is determined, again using the comparator 208, whether the programming (i.e. the write operation) of a logic “1” of the second MRAM cell has been failed or has been successful (operation 310). This operation is carried out in that the actual resistance value of the second MRAM cell representing the logic value being stored in the second MRAM cell is compared with the resistance value that would represent the logic value that should be stored in the second MRAM cell during the write operation.

In case the programming of the logic “1” of the second MRAM cell has also been failed (“Yes” in 310), the first word line current is increased by a predetermined amount (operation 312).

In a subsequent operation (operation 316), an increased first write current is applied to the first MRAM cell to program a logic “0.” The application of the increased first write current includes the application of the increased word line current and the first bit line current to the first MRAM cell, in other words, to the first word line and the first bit line, which are connected to the first MRAM cell. In other words, a further write attempt to program a logic “0” is carried out using an increased word line current in order to program the first MRAM cell.

Then, in 318, an increased second write current is applied to the second MRAM cell to program a logic “1”. The application of the increased second write current includes the application of the increased word line current and the initial second bit line current to the second MRAM cell, in other words, to the second word line and the second bit line, which are connected to the second MRAM cell. In other words, a further write attempt to program a logic “1” is carried out using an increased word line current in order to program the second MRAM cell.

The method then returns to 308.

Now referring back to 310, in case the programming of a logic “1” of the second MRAM cell has not failed (“No” in step 310), in other words, in case that only the programming of a logic “0” of the first MRAM cell has failed, the first bit line current is increased by a predetermined amount (operation 320) (see FIG. 3B).

In a subsequent operation (operation 322), an increased first write current is applied to the first MRAM cell to program a logic “0.” The application of the increased first write current in this case includes the application of the word line current and the increased first bit line current to the first MRAM cell to program a logic “0.” In other words, a further write attempt to program a logic “0” is carried out using an increased bit line current in order to program the first MRAM cell.

The method then returns to 308.

Now referring back to 308, in case the programming of a logic “0” of the first MRAM cell has not failed (“No” in 308), in other words, in case that the programming of a logic “0” of the first MRAM cell has been successful, it is determined, again using the read circuit 206 and the comparator 208, whether the programming (i.e., the write operation) of a logic “1” of the second MRAM cell has failed or has been successful (operation 324). This operation is carried out in that the actual resistance value of the second MRAM cell representing the logic value being stored in the second MRAM cell is compared with the resistance value that would represent the logic value that should be stored in the second MRAM cell during the write operation.

In case the programming of a logic “1” of the second MRAM cell has failed (“Yes” in 324), in other words, in case that only the programming of a logic “1” of the second MRAM cell has failed, the second bit line current is increased by a predetermined amount (operation 326) (see FIG. 3C).

In a subsequent operation (operation 328), an increased second write current is applied to the second MRAM cell. The application of the increased second write current in this case includes the application of the word line current and the increased second bit line current to the second MRAM cell to program a logic “1”. In other words, a further write attempt to program a logic “1” is carried out using an increased bit line current in order to program the second MRAM cell with a logic “1.”

The method then returns to 308.

In case the programming of a logic “1” of the second MRAM cell has not failed (“No” in 324), in other words, in case that the programming of a logic “1” of the second MRAM cell has also been successful, the programming method is completed in an end operation 330.

In other words, in a Stoner-Wohlfahrt type of switching of an MRAM cell, if the writing of a logic “0” and the writing of a logic “1” both fail during a write operation, the word line current of the word line the respective MRAM cells are connected to, will be increased. If only the writing of a logic “0” or the writing of a logic “1” fails during a write operation, the bit line current of the bit line the respective MRAM cell is connected to, will be increased corresponding to the write direction of the failing logic “0” or logic “1,” respectively.

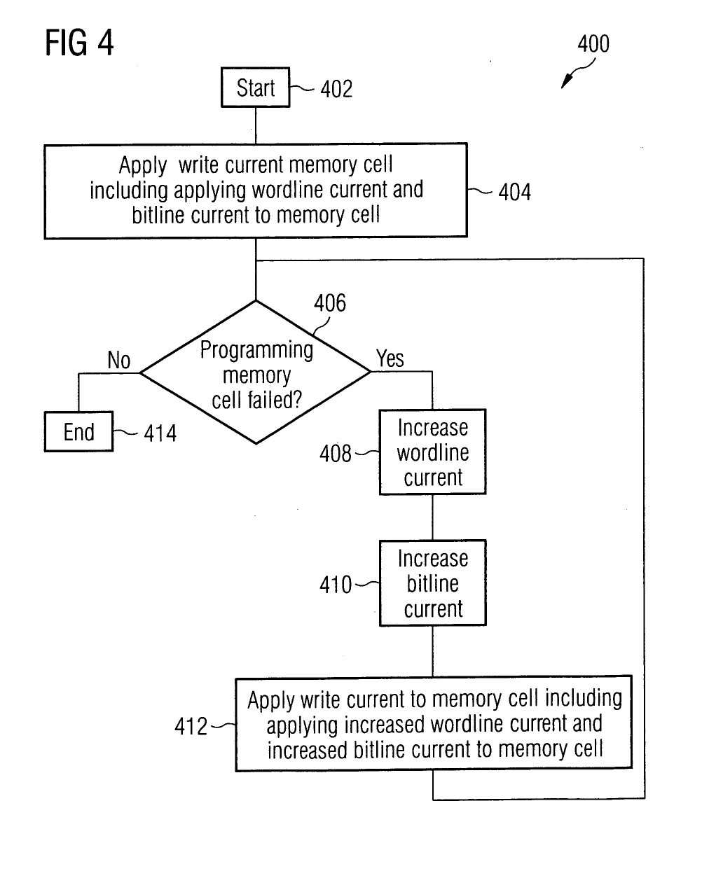

FIG. 4 shows a flow diagram 400 illustrating a method of programming a magneto resistive memory cell in accordance with another exemplary embodiment of the invention using rotational type switching. The method is implemented using the programming control unit 204, the read circuit 206 and the comparator 208.

As shown in FIG. 4, when a data item (a logic “0” or a logic “1”) should be written to a specified MRAM cell of the MRAM cell array 202, the method is started in step 402.

Then, a write current that is normally provided for writing a logic “0” or a logic “1,” respectively, into the selected MRAM cell is applied to the MRAM cell (step 404). The application of the write current includes the application of a word line current and a bit line current to the MRAM cell, in other words, to the word line and the bit line, which are connected to the MRAM cell.

Next, according to this embodiment of the invention, it is determined, using the read circuit 206 and the comparator 208, whether the programming (i.e. the write operation) of the MRAM cell has failed or has been successful (step 406). This step is carried out in that the actual resistance value of the MRAM cell representing the logic value being stored in the MRAM cell is compared with the resistance value that would represent the logic value that should be stored in the MRAM cell during the write operation.

In case the programming of the first MRAM cell has failed (“Yes” in step 406), the word line current is increased by a predetermined amount (step 408). Furthermore, the bit line current is also increased by a predetermined amount, which may be the same amount or a different amount than the amount by which the word line current is increased (step 410).

In a subsequent step (step 412), an increased write current is applied to the respective MRAM cell. The application of the increased write current includes the application of the increased word line current and the increased bit line current to the MRAM cell, in other words, to the word line and the bit line, which are connected to the MRAM cell. In other words, a further write attempt is carried out using an increased word line current and an increased bit line current in order to program the MRAM cell.

In case the programming of the first MRAM cell has not failed (“No” in step 406), in other words, in case that the programming of the MRAM cell has been successful, the programming method is completed in an end step 414.

In other words, in a rotational type of switching of an MRAM cell, if the writing of a logic “0” or of a logic “1” fails during a write operation, both the word line current of the word line and the bit line current of the bit line the respective MRAM cell is connected to, will be increased.

The methods described above are iterative methods that step-by-step increase the respective currents (and thereby the respectively applied magnetic fields) until the programming of the respective MRAM cell(s) has been successful. In other words, in case of an error, the write circuitry will adjust the programming write current and data will be written, read and compared again, until data are correctly programmed into the respective MRAM cell. In an embodiment of the invention, incoming data to be written into the storage area (i.e., the MRAM cell array 202) are, after the completion of the first write operation, immediately read again and compared in the comparator 208 with the value to be written. For the presented adjustment technique, it is provided that the storage area is written with a logic “0” bit and a logic “1” bit during a write cycle.

In addition to compensating an externally applied disturb field, the presented methods will also improve array yield by automatically correcting imperfect cells suffering by an offset shift occurring during fabrication.

Referring now back to FIG. 2, the MRAM device 200 in accordance with an exemplary embodiment of the invention further includes a magnetic field sensor 214, an output of which is coupled with an input of the programming control unit 204. The magnetic field sensor 214 is configured to measure the external magnetic field strength. In an alternative embodiment of the invention, a plurality of magnetic field sensors may be provided, e.g. two magnetic field sensors, which are oriented orthogonal with respect to each other. In this case, the two magnetic field sensors are capable to provide, in addition to the external magnetic field strength, information about the orientation of the external magnetic field, which may be used for an individual adaptation of the word line current and the bit line currents.

For a given magnetic programming field generated by the currents flowing through the word line and bit line, the memory cells may be programmed erroneously with a too small external magnetic field as well as with an external magnetic field being too high. Based on the output of the magnetic field sensor 214 or the magnetic field sensors, the current flowing through the word line and the bit lines, respectively may be increased as well as decreased (in other words, the word line current and the bit line currents may be increased as well as decreased). The decrease may be provided, e.g., in case that during the operation of the MRAM device 200, an increase of the external magnetic field strength is detected compared to an initial external magnetic field strength that may be measured in an initialization phase of the MRAM device 200 or after a predetermined re-calibration time period. The process in reducing the currents (word line current and bit line currents) is analogous compared with the embodiments, in which an increasing of the currents (word line current and bit line currents) is provided, only with opposite sign.

In one embodiment of the invention, a method for active write adjustment in an MRAM is provided, e.g., a method for active write adjustment in a Stoner-Wohlfahrt switching type MRAM or a method for active write adjustment in a rotational switching type MRAM.

While the invention has been shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes that come within the meaning and range of equivalency of the claims are intended to be embraced.

What is claimed is:

1. A method of programming a magneto resistive memory cell, the method comprising:
applying a first magnetic field to the magneto resistive memory cell;
determining whether the magneto resistive memory cell meets a programming criterion;
if the magneto resistive memory cell does not meet the programming criterion, applying a different magnetic field to the magneto resistive memory cell, the different magnetic field being higher or lower than the first magnetic field; and
if the magneto resistive memory cell still does not meet the programming criterion, repeating determining whether the magneto resistive memory cell meets the programming criterion and applying a different magnetic field applied to the magneto resistive memory cell until the magneto resistive memory cell meets the programming criterion.

2. The method of claim 1, wherein programming is performed using Stoner Wohlfarth switching mechanism.

3. The method of claim 1, wherein programming is performed using rotational type switching mechanism.

4. A method of programming a magneto resistive memory cell, the method comprising:
applying a first write current to the magneto resistive memory cell;
determining whether the magneto resistive memory cell meets a programming criterion;
if the magneto resistive memory cell does not meet the programming criterion, applying a different write current to the magneto resistive memory cell, the different write current being higher or lower than the first write current; and
if the magneto resistive memory cell still does not meet the programming criterion, repeating determining whether the magneto resistive memory cell meets the programming criterion and applying a different write current until the magneto resistive memory cell meets the programming criterion.

5. The method of claim 4 wherein programming is performed using Stoner Wohlfarth switching mechanism.

6. The method of claim 4 wherein programming is performed using rotational type switching mechanism.

7. A method of programming magneto resistive memory cells, the method comprising:
applying a first write current to a first magneto resistive memory cell to write a first programming value into the first magneto resistive memory cell;
applying a second write current to a second magneto resistive memory cell to write a second programming value into the second magneto resistive memory cell, the second programming value being different from the first programming value;
determining whether the magneto resistive memory cells meet a programming criterion;
if the first magneto resistive memory cell or the second magneto resistive memory cell does not meet the programming criterion, applying a third write current to the magneto resistive memory cell that fails to meet the programming criterion, the third write current being higher or lower than the first write current or the second write current, the third write current being applied via a first cell control line corresponding to a write direction of the magneto resistive memory cell that fails to meet the programming criterion; and
if the first magneto resistive memory cell and the second magneto resistive memory cell do not meet the programming criterion, applying a fourth write current to the magneto resistive memory cell that fails to meet the programming criterion, the fourth write current being higher or lower than the first write current or the second write current, the fourth write current being applied via a second cell control line.

8. The method of claim 7, wherein the first cell control line is a bit line of the magneto resistive memory cell that fails to meet the programming criterion.

9. The method of claim 7, wherein the second cell control line comprises a word line of the magneto resistive memory cell that fails to meet the programming criterion.

10. The method of claim 7, wherein applying the write currents comprises using Stoner Wohlfarth switching mechanism.

11. A method of programming magneto resistive memory cells, the method comprising:
applying a first write current to a first magneto resistive memory cell to write a first programming value into the first magneto resistive memory cell;
applying a second write current to a second magneto resistive memory cell to write a second programming value into the second magneto resistive memory cell, the second programming value being different from the first programming value;
determining whether the first and second magneto resistive memory cells meet a programming criterion; and
if the first magneto resistive memory cell or the second magneto resistive memory cell or both the first and second magneto resistive memory cells do not meet the programming criterion, applying a third write current to the magneto resistive memory cell or cells that fail to meet the programming criterion, the third write current being higher or lower than the first write current or the second write current, the third write current being applied via a first cell control line, and applying a fourth write current to the magneto resistive memory cell or cells that fails to meet the programming criterion, the fourth write current being higher or lower than the first write current or the second write current, the fourth write current being applied via a second cell control line.

12. The method of claim 11, wherein the first cell control line comprises a bit line.

13. The method of claim 11, wherein the second cell control line is a word line of the respective magneto resistive memory cell.

14. The method of claim 11, wherein programming is performed using rotational type switching mechanism.

15. A magneto resistive memory cell arrangement, comprising:
at least one magneto resistive memory cell; and
a programming control unit, the programming control unit causing:
a first magnetic field to be applied to the magneto resistive memory cell;
a second magnetic field to be applied to the magneto resistive memory cell if the magneto resistive memory cell does not meet a programming criterion, the second magnetic field being higher or lower than the first magnetic field; and
additional magnetic fields to be applied until the magneto resistive memory cell meets the programming criterion, each additional magnetic field being different from earlier magnetic fields.

16. A magneto resistive memory cell arrangement, comprising:
an array of a plurality of magneto resistive memory cells, each magneto resistive memory cell being coupled to a respective first cell control line and a respective second control line;
a programming control unit coupled to the first cell control lines and the second control lines, the programming control unit causing the following steps to be performed:
applying a first write current to a first magneto resistive memory cell to write a first programming value into the first magneto resistive memory cell;
applying a second write current to a second magneto resistive memory cell to write a second programming value into the second magneto resistive memory cell, the second programming value being different from the first programming value;
determining whether the magneto resistive memory cells meet a programming criterion;
if either the first magneto resistive memory cell or the second magneto resistive memory cell does not meet the programming criterion, applying a third write current to the magneto resistive memory cell that does not meet the programming criterion, the third write current being higher or lower than the first magnetic field or the second magnetic field, the third write current being applied via the first cell control line of the magneto resistive memory cell that does not meet the programming criterion; and
if both the first magneto resistive memory cell and the second magneto resistive memory cell do not meet the programming criterion, applying a fourth write current to the magneto resistive memory cells, the fourth write current being higher or lower than the first write current and the second write current, respectively, the fourth write current being applied via a second cell control line.

17. The magneto resistive memory cell arrangement of claim 16, wherein each first cell control line comprises a bit line.

18. The magneto resistive memory cell arrangement of claim 16, wherein each second cell control line comprises a word line.

19. A computer program product of programming a magneto resistive memory cell, when being executed by a computer, the computer program product including code to cause the performance of a plurality of programming steps, the programming steps comprising:
applying a first magnetic field to the magneto resistive memory cell;
determining whether the magneto resistive memory cell meets a programming criterion;
if the magneto resistive memory cell does not meet the programming criterion, applying a different magnetic field to the magneto resistive memory cell, the different magnetic field being higher or lower than the first magnetic field; and
wherein the programming steps of determining whether the magneto resistive memory cell meets a programming criterion and applying a different magnetic field are repeated until the magneto resistive memory cell meets the programming criterion.

20. A computer program product of programming a magneto resistive memory cell, when being executed by a computer, the computer program product including code to cause a performance of a plurality of programming steps, the programming steps comprising:
applying a first write current to a first magneto resistive memory cell to write a first programming value into the first magneto resistive memory cell;
applying a second write current to a second magneto resistive memory cell to write a second programming value into the second magneto resistive memory cell, the second programming value being different from the first programming value;
determining whether the magneto resistive memory cells meet a programming criterion; and
if the first magneto resistive memory cell and/or the second magneto resistive memory cell do not meet the programming criterion, applying a third write current to the first and second magneto resistive memory cells, the third write current being higher or lower than the first write current or the second write current, the third write current being applied via a first cell control line, and applying a fourth write current to the first and second magneto resistive memory cells, the fourth write current being higher or lower than the first magnetic field or the second magnetic field, the fourth write current being applied via a second cell control line.
